(19) United States
(12) Patent Application Publication
(10) Pub. No.: US 2010/0288324 A1
(43) Pub. Date: Nov. 18, 2010

(54) ENERGY CONVERSION BY EXOTHERMIC TO ENDOTHERMIC FEEDBACK

(76) Inventor: Marc Henness, Kissimmee, FL (US)

Correspondence Address: Daniel Law Offices, 37 N. Orange Ave., Suite 500, Orlando, FL, 32801, US

(21) Appl. No.: 12/777,543

(22) Filed: May 11, 2010

Related U.S. Application Data
(60) Provisional application No. 61/216,256, filed on May 16, 2009.
(60) Provisional application No. 61/268,189, filed on Jun. 9, 2009.

(51) Int. Cl. H01L 35/02

(52) U.S. Cl. 136/201; 136/205

(57) ABSTRACT

A system and method for converting kinetic to potential energy across a thermal gradient can include an endothermic unit for absorbing heat, an exothermic unit for releasing heat, and a control unit for receiving energy from an outside source to power the endothermic and exothermic units. The system can also include a first power generation unit having a plurality of thermoelectric elements which convert heat to an electrical potential across a thermal gradient, and a feedback unit for supplying the electrical potential generated by the first power generation unit to the control unit.

### CROSS-REFERENCE TO RELATED APPLICATIONS

This application claims the benefit of U.S. provisional Patent Application Nos. 61/216,256 filed on May 16, 2009 and U.S. provisional Patent Application No. 61/268,189 filed on Jun. 9, 2009 the entire contents of each of which are hereby incorporated by reference.

### BACKGROUND

1. Field of the Invention

The present invention relates generally to feedback of electric power generation. More particularly, it relates to a system and method for converting a portion of kinetic energy into potential energy across a thermal gradient.

2. Description of the Related Art

FIG. 1 illustrates one embodiment of a known Thermal-electric Generator (TEG) called a thermopile that is useful for understanding the inventive concepts disclosed herein. As shown, a single thermopile 10 typically includes two dissimilar metals 11 and 12 joined together at a common junction 13. The principle behind the thermocouple 10 is based on the Seebeck effect which states that an electrical current will flow at the junction (i.e. thermocouple) of a circuit made from two dissimilar metals at different temperatures. Common examples of this principle include electronic thermometers, and miniature thermoelectric transducers such as CP2-8-31-081 made by Melcor, USA.

However, the use of thermo-electric generators as a power source has traditionally been extremely limited due to the vast inefficiency of the devices which typically range from 3-9%. In this regard, in order to produce usable electricity, conventional TEG's must be exposed to a thermal gradient that is extremely high. This requirement means that a conventional thermo-electric generator would likely require more energy (in the form of heat generation) than the output (in the form of electricity) by the TEG. As a result, most thermo-electric generators are relegated to operating as a secondary power source and are often coupled with other technologies. For instance, thermo-electric generators are typically employed in solar power arrays, where there is an abundance of heat.

Accordingly, it would be beneficial to provide a highly efficient thermo-electric generator with an effective low cost thermal gradient producing device in order to convert the supplied kinetic energy into electricity across the thermal gradient. Several patents have been filed for thermoelectric energy conversion including: Aspden U.S. Pat. No. 5,065,085; Kondoh U.S. Patent Publication No. 2006-0016469; and Guevara U.S. Patent Publication No. 2003-0192582, however, none of these address the issues outlined above.

### SUMMARY OF THE INVENTION

The present invention is directed to a system for converting kinetic to potential energy across a thermal gradient. One embodiment of the present invention can include an endothermic unit for absorbing heat, an exothermic unit for releasing heat, and a control unit for receiving energy from an outside source to power the endothermic and exothermic units. The system can also include a first power generation unit having a plurality of thermoelectric elements which convert heat to an electrical potential across a thermal gradient, and a feedback unit for supplying the electrical potential generated by the first power generation unit to the control unit.

Another embodiment of the present invention can include a system as described above that further includes a plurality of power generation units.

Yet another embodiment of the present invention can include a method for implementing the system described above.

### BRIEF DESCRIPTION OF THE DRAWINGS

Presently preferred embodiments are shown in the drawings. It should be appreciated, however, that the invention is not limited to the precise arrangements and instrumentalities shown.

FIG. 1 illustrates one embodiment of a Thermal-electric Generator that is useful for understanding the embodiments disclosed herein.

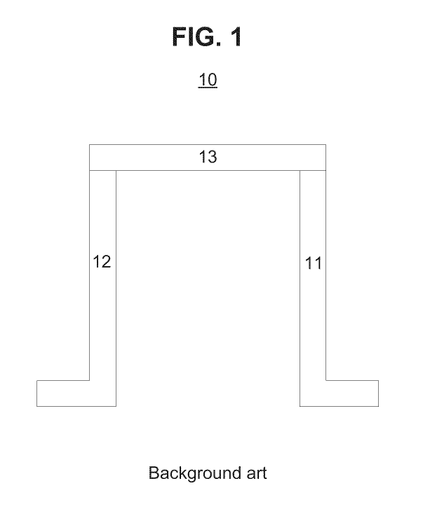

FIG. 2 illustrates one embodiment of a thermo-electric system in accordance with the present invention.

FIG. 3 illustrates a thermo-electric system in accordance with another embodiment present invention.

FIG. 4 illustrates a thermo-electric system in accordance with an alternate embodiment present invention.

FIG. 5 illustrates a thermo-electric system in accordance with an alternate embodiment present invention.

FIG. 6 illustrates a thermo-electric system in accordance with an alternate embodiment present invention.

FIG. 7 illustrates a thermo-electric system in accordance with an alternate embodiment present invention.

FIG. 8 is a flow chart illustrating a method for converting a portion of kinetic energy to potential energy across a thermal gradient producing system, in accordance with another embodiment of the present invention.

### DETAILED DESCRIPTION OF THE INVENTION

While the specification concludes with claims defining the features of the invention that are regarded as novel, it is believed that the invention will be better understood from a consideration of the description in conjunction with the drawings. As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the inventive arrangements in virtually any appropriately detailed structure. Further, the terms and phrases used herein are not intended to be limiting but rather to provide an understandable description of the invention.

As used throughout this document, a thermopile can include an array of thermocouples in a discrete package, aligned parallel to each other on a plane that is perpendicular to the direction of the thermal gradient. Moreover, a Thermo-electric Generator (TEG) can include a device for generating electric potential from a thermal gradient, one embodiment of which consists of multiple thermopiles arranged serially in relation to each other along the axis of the thermal gradient. Moreover, although described below as utilizing a heat pump, the inventive concepts disclosed herein are not so limited. To this end, virtually any sustainable thermal gradient producing device satisfying the criteria below can be utilized.

One example of a sustainable thermal gradient producing device is a conventional heat pump. In this sense, a heat pump absorbs heat energy from the endothermic side via an evaporator and releases the heat energy to the exothermic side via a condenser. Both the endothermic and exothermic reactions are multiples of the input energy needed to trigger the process. To this end, the coefficient of performance also known as the Primary Energy Ratio (PER) of a thermal gradient producing device (i.e., heat pump) can be defined by the equation:

PER=(Q+W)/W

where Q is the kinetic energy absorbed in the endothermic process, and W is the energy provided to the heat pump to do the work. In this case, work (W) is defined as both the energy used by the heat pump to generate the thermal difference and the energy lost in a delivery mechanism such as a compressor.

For purposes of describing this invention we will define Primary Energy Ratio (PER) as the Energy Pumping ratio of the Endothermic, and Exothermic process which is used for the generation of the Thermal Gradient. Whereas we will define the Coefficient of Performance to be that of the overall system defined by the equation:

COP=(Q+W)/(W−C)

where Q is the kinetic energy absorbed in the endothermic process, W is the energy needed for the heat pumping process to do the work, and C is the energy recollected by the TEG.

As stated above, a thermo-electric generator (TEG) is a device that can convert kinetic to potential energy by transforming heat into electricity. A TEG can include a single thermopile or an array of thermopiles arranged electrically in series and thermally in parallel in order to achieve high electrical and thermal conductance. One example of a TEG is described in U.S. Patent Publication No. 2008/0283110, to Jin et al., the contents of which are incorporated herein by reference.

To this end, Jin describes a TEG capable of converting a 100° Celsius thermal gradient into electric potential at efficiencies of 40-80%. Of course one of skill in the art will recognize that this is but one example of a TEG that can be used in combination with the inventive concepts disclosed herein. For instance, in one embodiment, an array of thermopiles may also be incorporated into a semiconductor material that includes low energy p-type semiconductor elements and higher energy n-type semiconductor elements, or the array may be formed using materials which are known to convert heat to an electrical current when the ends thereof are exposed to a temperature differential.

In either case, for the purposes of this disclosure, any TEG having an efficiency (E) defined by the equation: E=P/(Q+W), where P is the potential energy generated by the TEG, Q is the kinetic energy provided to the TEG and W is the energy necessary to do the work can be utilized.

When introducing a TEG as described above within the thermal gradient of a thermal gradient producing device, such as a heat pump, for example, it is possible to generate potential energy which can be used by external applications. To this end, this energy can be transmitted back via the transmission lines used to provide an initial energy to the system, or can be supplied directly to other devices. Alternatively, the potential energy can be fed back into the system in order to greatly improve the overall COP of the heat pump itself, with the COP approaching infinity as E approaches 1/(PER). For example, if the Primary Energy Ratio (PER) of the heat pump is 5, then a TEG having an efficiency (E) of 5% could improve the COP of the overall system from 5 to 6.7.

Moreover, in another embodiment, a system that includes a TEG arranged within the thermal gradient of a heat pump satisfying the equation: E>1/(PER), can potentially generate enough potential electric energy to sustain the future power requirements of the heat pump system itself. For example, a TEG having an efficiency (E) of 20% could potentially provide enough electrical energy to sustain the future operation of the same heat pump. Further, in the same example, utilizing a TEG having an efficiency (E) that is greater than 20% can potentially enable the system to produce more potential energy than the heat pump needs to operate.

With respect to this invention and the embodiments outlined below, it is noted that each embodiment complies in full with the laws of thermodynamics, and in particular the Second Law of Thermodynamics.

To this end, the operation of the system is based on the availability of kinetic energy in the form of excited matter, and all matter with a kinetic energy above Zero Kelvin emits Black Body radiation. Hence as the system remains running, the kinetic energy needed to operate the system will eventually decay to Entropy in the form of Black Body Radiation. However, so long as there is mater with sufficient Kinetic Energy for the Heat Pump to efficiently absorb, with a PER sufficient for the Power Generator to feed it, the system can continue to provide potential energy for general use, without other power sources.

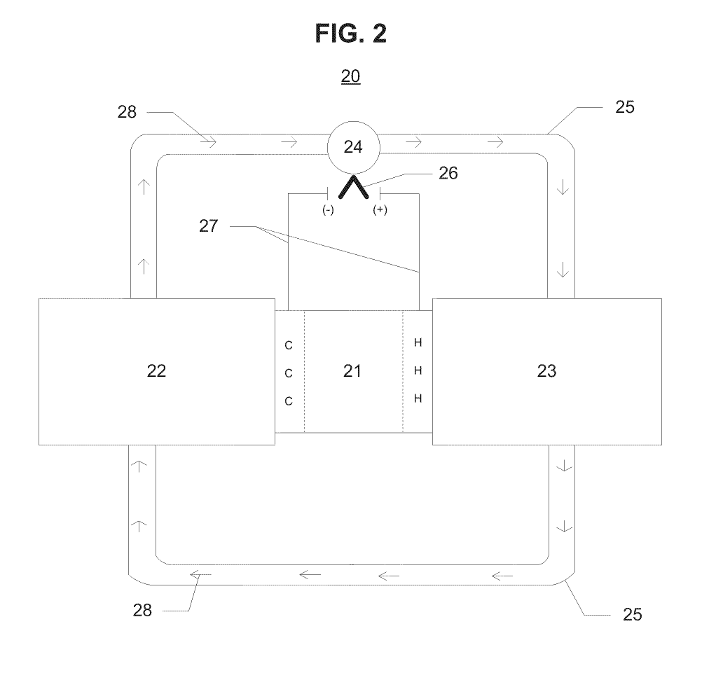

FIG. 2 illustrates one embodiment of a thermo-electric system 20 in accordance with the inventive concepts disclosed herein. Specifically, FIG. 2 illustrates a TEG disposed between an evaporator and a condenser.

System 20 can include a TEG 21, an evaporator 22, a condenser 23 a compressor 24 and a circulation chamber 25. The evaporator 22 includes a cold temperature where pressurized refrigerant 28 contained in the circulation chamber 25 is allowed to expand, boil and evaporate. During this change of state from liquid to gas, energy in the form of heat is absorbed as an endothermic process. The compressor 24 acts as the refrigerant pump and recompresses the gas into a liquid. The compressor operates on electricity and the required amount fluctuates depending on the temperature difference between the evaporator and the condenser. The condenser 23 can include a hot temperature that expels the heat absorbed by the evaporator plus any additional heat produced during compression by the compressor 24.

In one preferred embodiment, the evaporator 22, condenser 23, compressor 24 and circulation chamber 25 can comprise an industrial grade closed-cycle phase change heat pump capable of generating temperature differentials in excess of 50°-100° Celsius with a Primary Energy Ratio (PER) exceeding 2. However, other thermal gradient producing systems are also contemplated. In another preferred embodiment, TEG 21 can include a hot portion H and a cold portion C, and having an efficiency (E) that is greater than 1/[PER (of the Heat Pump)]. In operation, the hot section H of the TEG 21 can be placed against or adjacent to the condenser 23, while the cold section C of the TEG 21 can be placed against or adjacent to the evaporator 22. As described above, the condenser 23 operates at an extremely high heat, whereas the evaporator 22 operates at an extremely low heat. As such, the resulting temperature differential (i.e. thermal gradient) acting upon the hot and cold sections of the TEG 21 can supply the necessary temperature gradient for the TEG to produce a voltage. The resulting power can then be fed directly to the electrical input 26 of the compressor 24 via wires 27. Outside electricity (not shown) must also be provided to the electrical input of the system in order to create the initial thermal gradient.

A thermo-electric system 20, as described above would thus be capable of providing long lasting power which could supply continued heating, or cooling of a space, along with a small amount of extra Potential Energy for other uses. Additionally, a TEG 21 could significantly improve the overall energy efficiency, and space temperature regulation of a Heat Pump under conditions when the space being heated or cooled is close to it's preferred temperature.

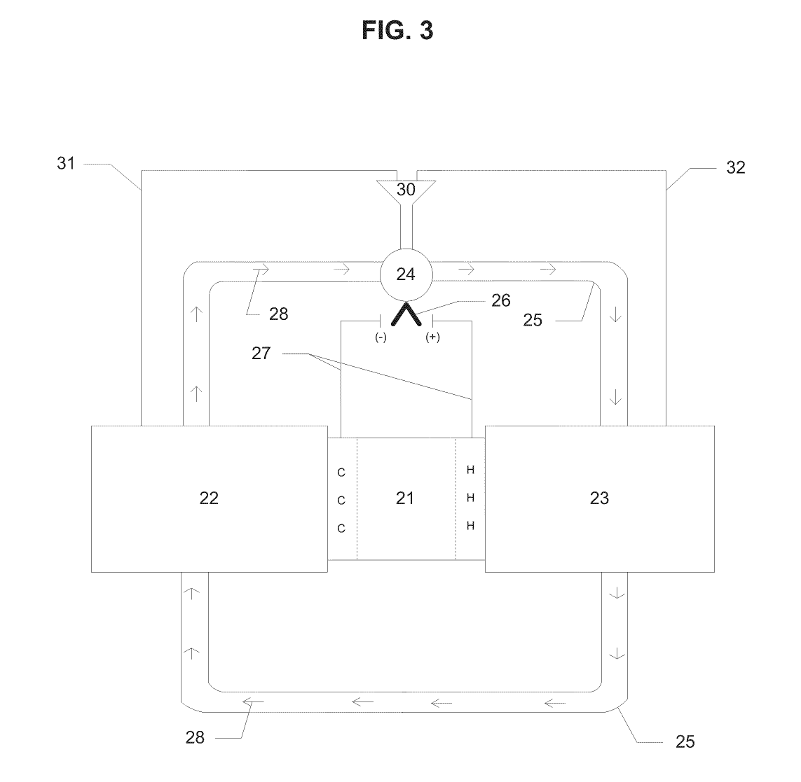

FIG. 3 illustrates an alternate embodiment of the thermo-electric system described above that further includes servo unit 30. Owing to the fact that a Heat Pump's PER will significantly drop at high temperature differentials, and a TEG's Efficiency will significantly drop at low temperature differentials, servo unit 30 can be included in the system to monitor the temperature differential, and regulate the input power such that optimum differentials are maintained. As such, servo 30 can include an evaporator monitor 31 and a condenser monitor 32 for reporting the temperature of the respective components to the servo 20. Temperature monitoring devices of this type are known and can include, for example a thermostat electrically connected to the servo or other similar means of temperature reporting device.

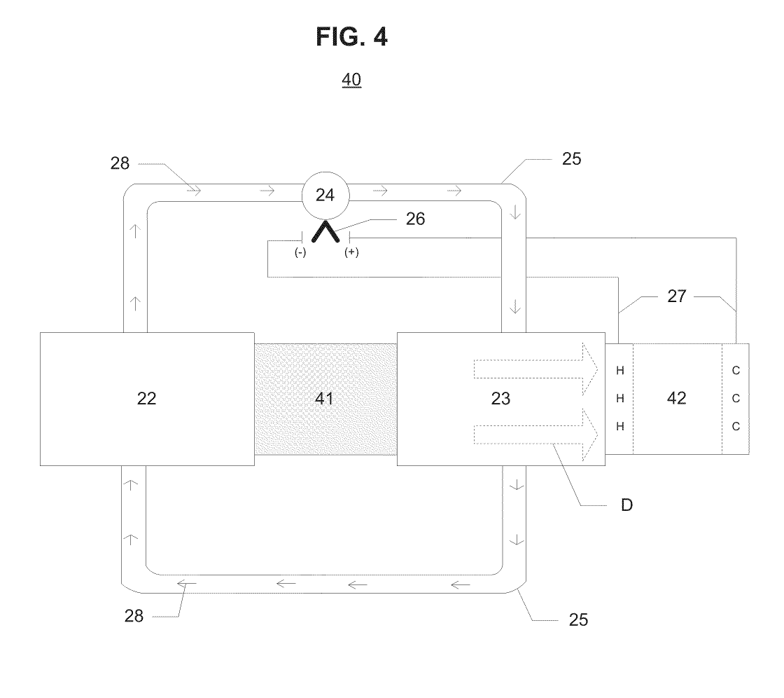

FIG. 4 illustrates a thermo-electric system in accordance with another embodiment of the present invention. As shown, a thermo-electric system 40 can include a low thermal conductive barrier 41 interposed between the evaporator 22 and the condenser 23. The system can further include a TEG 42 disposed between the condenser 23 and the environment to which the condenser is providing heat (See arrow D). To this end, the heat from the condenser can be used for general heating purposes, or for disposing of waste heat if the system is being used for general cooling purposes (i.e. air conditioning). As used herein, a thermal conductive barrier can include foam board or any other known insulative material.

In operation, the hot section H of the TEG 42 can be placed against or adjacent to the condenser 23, while the cold section C of the TEG 42 can be open to external environmental conditions. As such, the resulting temperature differential between the hot condenser 23 and the outside air can supply the necessary thermal gradient for the TEG to produce a voltage. The resulting power can then be fed directly to the electrical input 26 of the compressor 24 via wires 27.

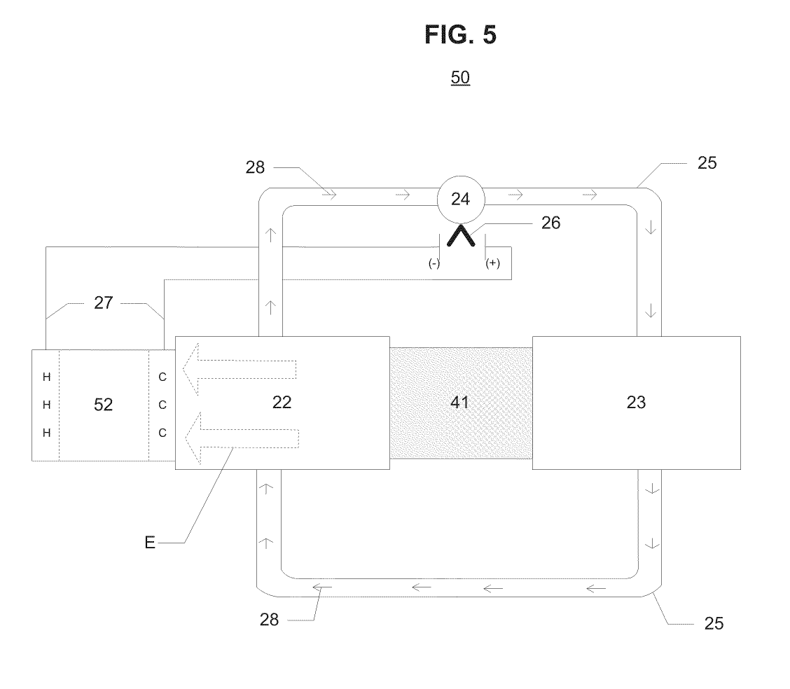

FIG. 5 illustrates a thermo-electric system in accordance with another embodiment of the present invention. As shown, a thermo-electric system 50 can include a low thermal conductive barrier 41 interposed between the evaporator 22 and the condenser 23. The system can further include a TEG 52 disposed between the evaporator 22 and the environment to which the evaporator is providing cold air (See arrow E).

In operation, the cold section C of the TEG 52 can be placed against or adjacent to the evaporator 22, while the hot section h of the TEG 52 can be open to external environmental conditions. As such, the temperature differential between the cold evaporator 22 and the outside air can supply the necessary thermal gradient for the TEG to produce a voltage. The resulting power can then be fed directly to the electrical input 26 of the compressor 24 via wires 27.

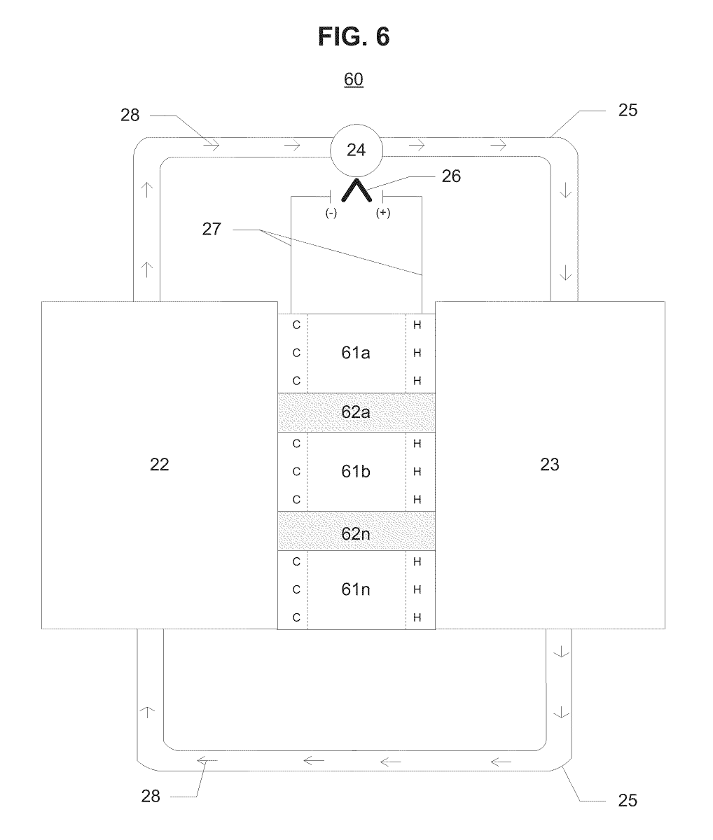

Although described above as a system having a single TEG unit, the inventive concepts also relate to the use of multiple independent TEG units working in unison. For instance, FIG. 6 illustrates one embodiment of a thermo electric system 60 having multiple TEG units interposed between the evaporator and condenser.

System 60 can include a plurality of TEG units 61a-61n interposed between the evaporator 22, and the condenser 23. In one embodiment, each of the TEG units can be separated by a low conductive protective barrier 62a-62n. As with the above examples, the hot sections H of the plurality of TEG units 61a-61n can be placed against or adjacent to the condenser 23, while the cold sections C of the plurality of TEG units 61a-61n can be placed against or adjacent to the evaporator 22, thus creating the thermal gradient necessary to produce a voltage which can then be fed directly to the electrical input 26 of the compressor 24 via wires 27. By utilizing such a configuration, independent TEG units can be added or taken away from the system in order to satisfy individual performance/power requirements.

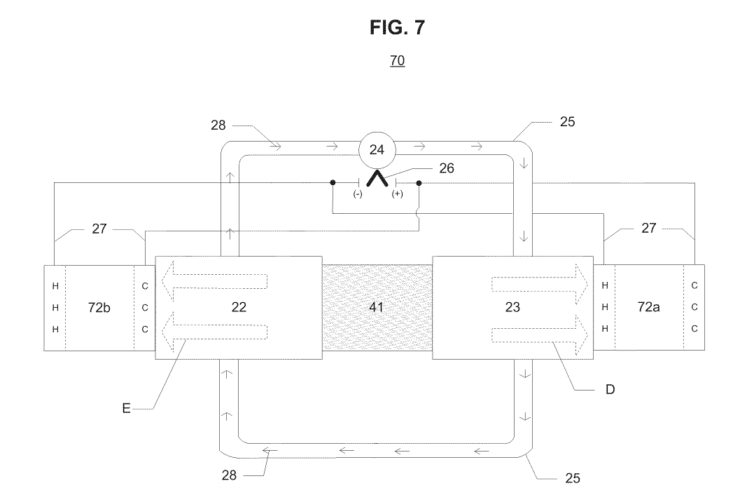

FIG. 7 illustrates an alternate embodiment of a system 70 in which multiple TEG units are utilized. As shown, a thermo-electric system 70 can include a low thermal conductive barrier 41 interposed between the evaporator 22 and the condenser 23. The system can further include a first TEG 72a disposed between the condenser 23 and the environment to which the condenser is providing heat (See arrow D), and a second TEG 72b disposed between the evaporator 22 and the environment to which the evaporator is providing cold air (See arrow E).

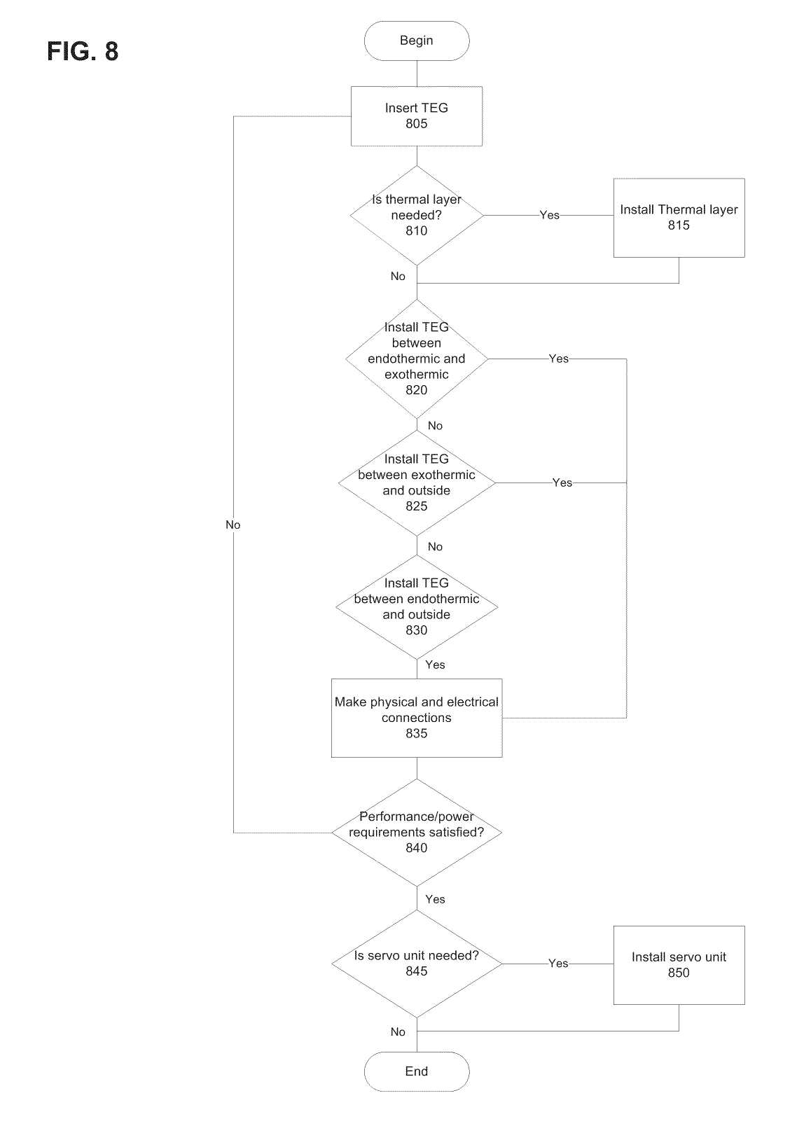

FIG. 8 is a flow chart illustrating a method 800 for converting a portion of kinetic energy to potential energy across a thermal gradient producing system, in accordance with another embodiment of the present invention. Method 800 can be performed by a system as described with reference to FIGS. 2-7 above.

Accordingly, method 800 can begin in step 805 where the decision to place a thermo-electric generator (such as TEG 21, for example) within the thermal gradient of a thermal gradient producing system (such as a heat pump, for example) has been made.

In step 810 a decision as to whether a thermal insulative layer is needed can be made. If the layer is needed, the method can proceed to step 815 where the thermal layer is installed into the system, otherwise the method will proceed to step 820.

In step 820, the TEG can be positioned between the endothermic side and the exothermic side of the system. If this option is selected, the method will proceed to step 835, otherwise the method will proceed to step 825.

In step 825, one side of the TEG can be affixed, or adjacent to the exothermic side of the system and the other side of the TEG can face the outside environment. If this option is selected, the method will proceed to step 835, otherwise the method will proceed to step 830.

In step 830, one side of the TEG can be affixed, or adjacent to the endothermic side of the system and the other side of the TEG can face the outside environment, and the system can proceed to step 835.

In step 835, the physical and electrical components of the TEG can be installed into the system. In step 840 a determination can be made as to whether the power and/or performance criteria of the system are met. If yes, the method can proceed to step 845, otherwise the method will return to step 805 where an additional TEG can be installed.

In step 845, a determination as to whether a temperature monitoring and power regulation unit (such as monitors 30-31 and a servo unit 30, for example) are desired can be made.

If yes, the method will proceed to step 850 where the unit can be installed and the method will terminate. If no, the method will terminate.

By incorporating the inventive concepts disclosed herein, it is possible to convert a portion of kinetic energy into potential energy across a thermal gradient. Such potential energy can be utilized to provide power to external devices or can be fed back into the thermal gradient producing system, thus greatly improving the overall COP of the system itself.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed.

Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A thermo-electric system for converting kinetic to potential energy across a thermal gradient, said system comprising:
an endothermic unit configured to absorb heat, said endothermic unit having a cold portion;
an exothermic unit configured to release heat, said exothermic unit having a hot portion;
a control unit configured to receive an energy from an outside source to power the endothermic and exothermic units;
a first power generation unit having a hot section, a cold section and a plurality of thermoelectric elements configured to convert heat to an electrical potential, said plurality of thermoelectric elements being positioned in electrical series and thermal parallel across the thermal gradient; and
a feedback unit configured to supply the electrical potential generated by the first power generation unit to the control unit.

2. The thermo-electric system of claim 1, wherein the first power generation unit is interposed between the endothermic unit and the exothermic unit, and
the hot section of the first power generation unit is configured to interact with the hot portion of the exothermic unit and the cold section of the first power generation unit is configured to interact with the cold portion of the endothermic unit.

3. The thermo-electric system of claim 2 further comprising:
one or more secondary power generation units, each having a hot section, a cold section and a plurality of thermoelectric elements configured to convert heat to an electrical potential, said plurality of thermoelectric elements being positioned in electrical series and thermal parallel across a thermal gradient,
wherein the hot section of each of the one or more secondary power generation units is configured to interact with the hot portion of the exothermic unit and the cold section of each of the one or more secondary power generation units is configured to interact with the cold portion of the endothermic unit.

4. The thermo-electric system of claim 1 further comprising:
a first sensor configured to report a temperature of the endothermic unit;
a second sensor configured to report a temperature of the exothermic unit; and
a servo unit configured to regulate the control unit such that an optimum temperature differential between said endothermic and exothermic units is maintained.

5. The thermo-electric system of claim 1 further comprising:
a low thermal conductive barrier interposed between the endothermic unit and the exothermic unit,
wherein the cold section of the first power generation unit is configured to interact with the cold portion of the endothermic unit and the hot section of the first power generation unit is configured to interact with an outside temperature.

6. The thermo-electric system of claim 1 further comprising:
a low thermal conductive barrier interposed between the endothermic unit and the exothermic unit,
wherein the hot section of the first power generation unit is configured to interact with the hot portion of the exothermic unit and the cold section of the first power generation unit is configured to interact with an outside temperature.

7. The thermo-electric system of claim 6 further comprising:
a secondary power generation unit having a hot section, a cold section and a plurality of thermoelectric elements configured to convert heat to an electrical potential,
wherein the cold section of the second power generation unit is configured to interact with the cold portion of the endothermic unit and the hot section of the second power generation unit is configured to interact with an outside temperature.

8. The thermo-electric system of claim 1 wherein the electrical potential generated by the first power generation unit is used to supplement the energy from the outside source.

9. The thermo-electric system of claim 1 wherein the electrical potential generated by the first power generation unit is greater than the energy received from the outside source.

10. The thermo-electric system of claim 1 wherein the electrical potential generated by the first power generation unit is fed to the outside source.

11. The thermo-electric system of claim 1 wherein the endothermic and exothermic units are components of a closed cycle phase change heat pump with a Primary Energy Ratio exceeding 2.

12. The thermo-electric system of claim 11, wherein the electrical potential generated by the first power generation unit is used to improve a coefficient of performance of the heat pump.

13. A method for converting kinetic to potential energy across a thermal gradient, said method comprising:
absorbing heat, via an endothermic unit having a cold portion;
releasing heat, via an exothermic unit having a hot portion;
receiving an energy via a control unit;
providing the received energy to the endothermic and exothermic units;
converting heat to an electrical potential, via a first power generation unit,
wherein said first power generation unit includes a hot section, a cold section and a plurality of thermoelectric elements positioned in electrical series and thermal parallel across a thermal gradient; and
providing the electrical potential to the control unit.

14. The method for converting kinetic to potential energy of claim 13, further comprising:
placing the first power generation unit between the endothermic unit and the exothermic unit,
wherein the hot section of the first power generation unit is adjacent to the hot portion of the exothermic unit and the cold section of the first power generation unit is adjacent to the cold portion of the endothermic unit.

15. The method for converting kinetic to potential energy of claim 13, further comprising:
providing a first temperature sensor to the endothermic unit;
providing a second temperature sensor to the exothermic unit;
installing a servo unit on the control unit; and
maintaining an optimum temperature differential between said endothermic and exothermic units.

16. The method for converting kinetic to potential energy of claim 13, further comprising:
converting heat to an electrical potential, via a second power generation unit,
wherein said second power generation unit includes a hot section, a cold section and a plurality of thermoelectric elements positioned in electrical series and thermal parallel across a thermal gradient.

17. The method for converting kinetic to potential energy of claim 16, further comprising:
supplementing the received energy at the control unit with the electrical potential generated by the first and second power generation units.

18. A thermo-electric system for converting kinetic to potential energy across a thermal gradient, said system comprising:
means for performing an endothermic reaction;
means for performing an exothermic reaction,
means for receiving external energy and sending said energy to means for performing endothermic and exothermic reactions;
means for converting heat to an electrical potential across a thermal gradient; and
means for providing the electrical potential to the means for receiving.
